(19) United States
(12) Patent Application Publication
(10) Pub. No.: US 2025/0349515 A1
(43) Pub. Date: Nov. 13, 2025

(54) RF AND DC FREQUENCY AND PHASE LOCKED PULSED EDGE TILT CONTROL SYSTEM

(71) Applicant: Lam Research Corporation, Fremont, CA (US)

(72) Inventor: Seyed Jafar JAFARIAN-TEHRANI, Fremont, CA (US)

(21) Appl. No.: 18/871,473

(22) PCT Filed: May 25, 2023
(86) PCT No.: PCT/US2023/067460

§ 371 Date: Dec. 3, 2024

Related U.S. Application Data
(60) Provisional application No. 63/350,231, filed on Jun. 8, 2022.

(51) Int. Cl. H01J 37/32; H01L 21/683

(52) U.S. Cl. CPC H01J 37/32183; H01J 37/32642; H01J 37/32697; H01L 21/6833

(57) ABSTRACT

A method performed within a plasma chamber. The method including providing a first power signal to an electrostatic chuck (ESC). The method including providing a second power signal to an edge ring. The method including measuring an amplitude of a current signal occurring at an interface between the ESC and the edge ring. The method including adjusting one or more parameters of the first power signal and the second power signal to achieve a minimum amplitude of the current signal. The method including determining a phase relationship between a phase of the current signal and a phase of a reference signal to determine a direction of ion tilt at the interface. The method including adjusting at least one parameter of the second power signal to achieve a predetermined angle of the ion tilt at the interface based on the phase relationship and the amplitude of the current signal.

### TECHNICAL FIELD

The present embodiments relate to semiconductor fabrication, and more specifically to systems and methods for measuring RF and pulsed DC current at the interface between an electrostatic chuck and an edge ring to balance the power and/or voltages at the interface in order to achieve a desired ion tilt at the edge of the wafer.

### BACKGROUND OF THE DISCLOSURE

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to a plasma generated within a plasma processing volume. Plasma contains various types of radicals, electrons, as well as positive and negative ions. The chemical reactions of the various radicals, electrons, positive ions, and negative ions are used to etch features, surfaces and materials of a wafer.

For example, when a process gas is supplied into the plasma processing chamber, a radio frequency (RF) signal provides power and is applied to at least one of the electrodes of the plasma processing chamber to form an electric field between the electrodes. The process gas is turned into plasma by the RF signal, thereby performing plasma etching on a predetermined layer disposed on the wafer. Unfortunately, during wafer processing, the plasma may result in an ion angular spread (e.g., ion tilt angles) occurring along the extreme edge of the wafer which may cause non-uniformity of features along the extreme edge of the wafer.

It is in this context that embodiments of the disclosure arise.

### SUMMARY

The present embodiments relate to methods and apparatus for measuring RF and pulsed DC current at the interface between an electrostatic chuck and an edge ring to balance the power and/or voltages at the interface in order to achieve a desired ion tilt at the edge of the wafer. Several inventive embodiments of the present disclosure are described below.

Embodiments of the present disclosure provide for a method for achieving a predetermined factor associated with an edge region within a plasma chamber is described. The method including providing a first power signal to an electrostatic chuck (ESC) within a plasma chamber. The method including providing a second power signal to an edge ring within the plasma chamber. The method including measuring an amplitude of a low frequency current signal occurring at an interface between the ESC and the edge ring. The method including adjusting one or more parameters of the first power signal and the second power signal to achieve a minimum amplitude of the low frequency current signal. The method including determining a phase relationship between a phase of the low frequency current signal and a phase of a reference signal to determine a direction of ion tilt at the interface between the ESC and the edge ring. The method including adjusting at least one parameter of the second power signal to achieve a predetermined angle of the ion tilt at the interface between the ESC and the edge ring based on the phase relationship and the amplitude of the low frequency current signal.

Other embodiments of the present disclosure provide for a non-transitory computer-readable medium storing a computer program for performing a method for achieving a predetermined factor associated with an edge region within a plasma chamber. The computer-readable medium including program instructions for providing a first power signal to an electrostatic chuck (ESC) within a plasma chamber. The computer-readable medium including program instructions for providing a second power signal to an edge ring within the plasma chamber. The computer-readable medium including program instructions for measuring an amplitude of a low frequency current signal occurring at an interface between the ESC and the edge ring. The computer-readable medium including program instructions for adjusting one or more parameters of the first power signal and the second power signal to achieve a minimum amplitude of the low frequency current signal. The computer-readable medium including program instructions for determining a phase relationship between a phase of the low frequency current signal and a phase of a reference signal to determine a direction of ion tilt at the interface between the ESC and the edge ring. The computer-readable medium including program instructions for adjusting at least one parameter of the second power signal to achieve a predetermined angle of the ion tilt at the interface between the ESC and the edge ring based on the phase relationship and the amplitude of the low frequency current signal.

Still other embodiments of the present disclosure provide for a computer system including a processor and memory coupled to the processor, the memory having stored therein instructions that, if executed by the computer system, cause the computer system to execute a method for achieving a predetermined factor associated with an edge region within a plasma chamber. The method including providing a first power signal to an electrostatic chuck (ESC) within a plasma chamber. The method including providing a second power signal to an edge ring within the plasma chamber. The method including measuring an amplitude of a low frequency current signal occurring at an interface between the ESC and the edge ring. The method including adjusting one or more parameters of the first power signal and the second power signal to achieve a minimum amplitude of the low frequency current signal. The method including determining a phase relationship between a phase of the low frequency current signal and a phase of a reference signal to determine a direction of ion tilt at the interface between the ESC and the edge ring. The method including adjusting at least one parameter of the second power signal to achieve a predetermined angle of the ion tilt at the interface between the ESC and the edge ring based on the phase relationship and the amplitude of the low frequency current signal.

These and other advantages will be appreciated by those skilled in the art upon reading the entire specification and the claims.

### BRIEF DESCRIPTION OF THE DRAWINGS

The embodiments may best be understood by reference to the following description taken in conjunction with the accompanying drawings.

FIG. 1A illustrates an embodiment of a capacitive coupled plasma (CCP) processing system utilized for etching operations including radio frequency (RF) power sources, in accordance with an implementation of the disclosure.

FIGS. 1B-1 through 1B-5 illustrate embodiments of a capacitive coupled plasma (CCP) processing system utilized for etching operations including direct current (DC) pulsed power sources, in accordance with one embodiment of the present disclosure.

FIG. 2A illustrates a control system utilized for achieving a desired ion tilt at the edge of a wafer by measuring current (e.g., radio frequency and/or direct current) at the interface between an ESC and an edge ring, in accordance with one embodiment of the disclosure.

FIG. 2B illustrates a sensor configured to measure the current (e.g., RF and/or pulsed DC current) at the interface between an ESC and an edge ring, in accordance with one embodiment of the present disclosure.

FIG. 3 is a flow diagram illustrating a method for achieving a desired ion tilt at the edge of a wafer by measuring RF current at the interface between an ESC and an edge ring, in accordance with one embodiment of the disclosure.

FIG. 4 shows the effective local electric field across the interface is influenced by the electric field of the wafer plasma sheath and the electric field of the edge ring plasma sheath.

### DETAILED DESCRIPTION

Although the following detailed description contains many specific details for the purposes of illustration, anyone of ordinary skill in the art will appreciate that many variations and alterations to the following details are within the scope of the present disclosure. Accordingly, the aspects of the present disclosure described below are set forth without any loss of generality to, and without imposing limitations upon, the claims that follow this description.

Generally speaking, the various embodiments of the present disclosure describe methods and apparatus for achieving a desired ion tilt at an edge of a wafer. In particular, it is beneficially recognized that the amount of RF current passing through the interface of the ESC and the edge ring has a correlation to ion tilt angles. That is, when the phase between voltage sensors associated with RF generators feeding the ESC and the edge ring are at a nominal value for a given edge ring voltage setpoint, the pulsed DC or RF current at the interface of the ESC and edge ring is at a minimum. As such, focusing on measurement of the RF current across the interface of the ESC and the edge ring, rather than voltage measurements of RF power signals at match networks remote from the interface, provides for a more accurate determination of when the power and/or voltages of the power generators are balanced to achieve a near vertical ion tilt occurring at the interface. Further, by adjusting the power or phase relationship between the voltage signals of the RF power generators, the system draws more power from the electrode in the ESC towards the edge ring at the interface, or pushes more power at the interface towards the ESC. This adjustment to the power or phase relationship provides a means to control the vector direction of the electric field locally at the interface, and hence a means to control the ion tilt of the etching positive ions at the interface.

Advantages of the various embodiments, disclosing methods and apparatus for achieving a desired ion tilt at an edge of a wafer through a measurement of the RF current passing through the interface of the ESC and edge ring and adjusting power or phase relationships of the RF generators result in a better correlation between measured values and the actual ion tilt at the interface rather than relying on sensor measurement that are located remote from the interface (e.g., at the match networks adjacent to the power generators). In that manner, a better and more accurate control mechanism is realized for achieving a desired ion tilt at the edge of the wafer. Other advantages include providing a more direct measurement of the current occurring at the interface that is independent of the drive impedances of the power sources supplying power to the ESC and the edge ring. Still other advantages include a lower cost edge control RF delivery system using a more direct way to achieve a desired result (e.g., ion tilt) at less total power required for a particular etch rate.

With the above general understanding of the various embodiments, example details of the embodiments will now be described with reference to the various drawings. Similarly numbered elements and/or components in one or more figures are intended to generally have the same configuration and/or functionality. Further, figures may not be drawn to scale but are intended to illustrate and emphasize novel concepts. It will be apparent, that the present embodiments may be practiced without some or all of these specific details. In other instances, well-known process operations have not been described in detail in order not to unnecessarily obscure the present embodiments.

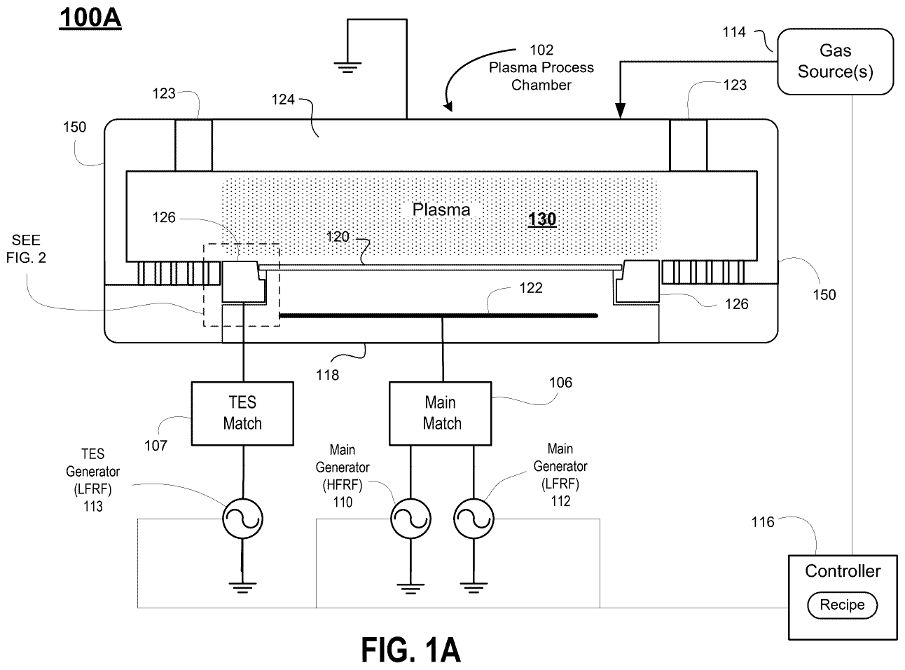

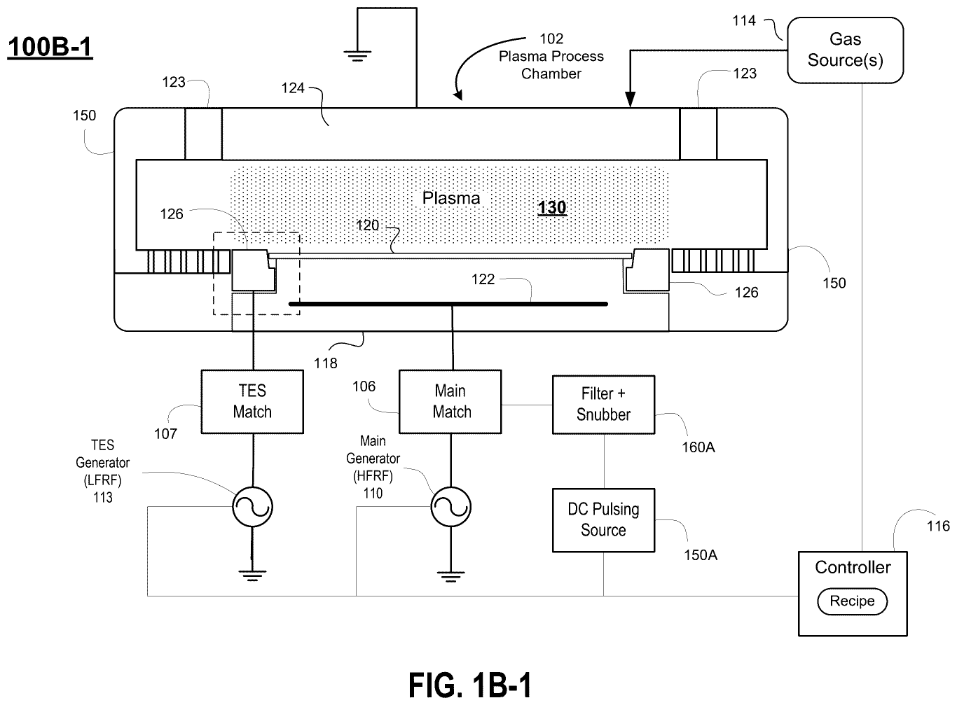

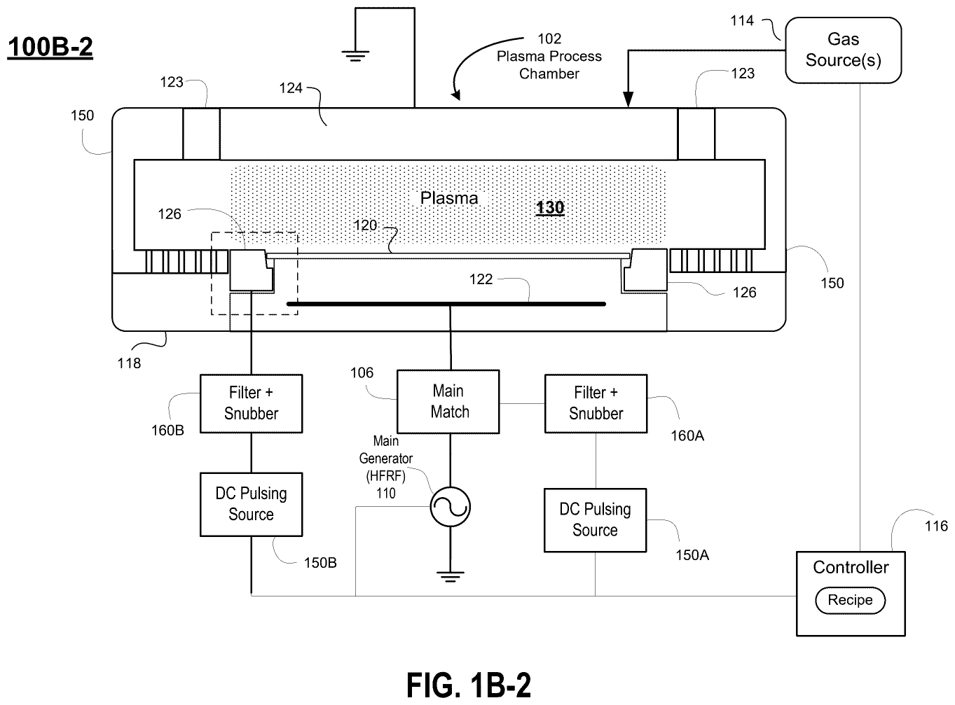

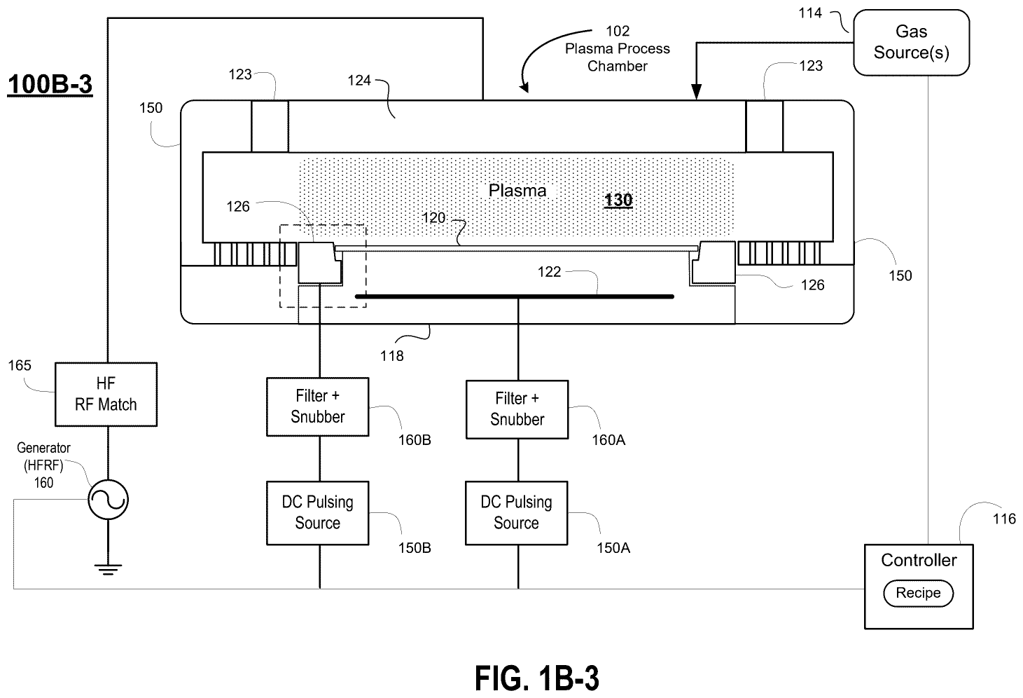

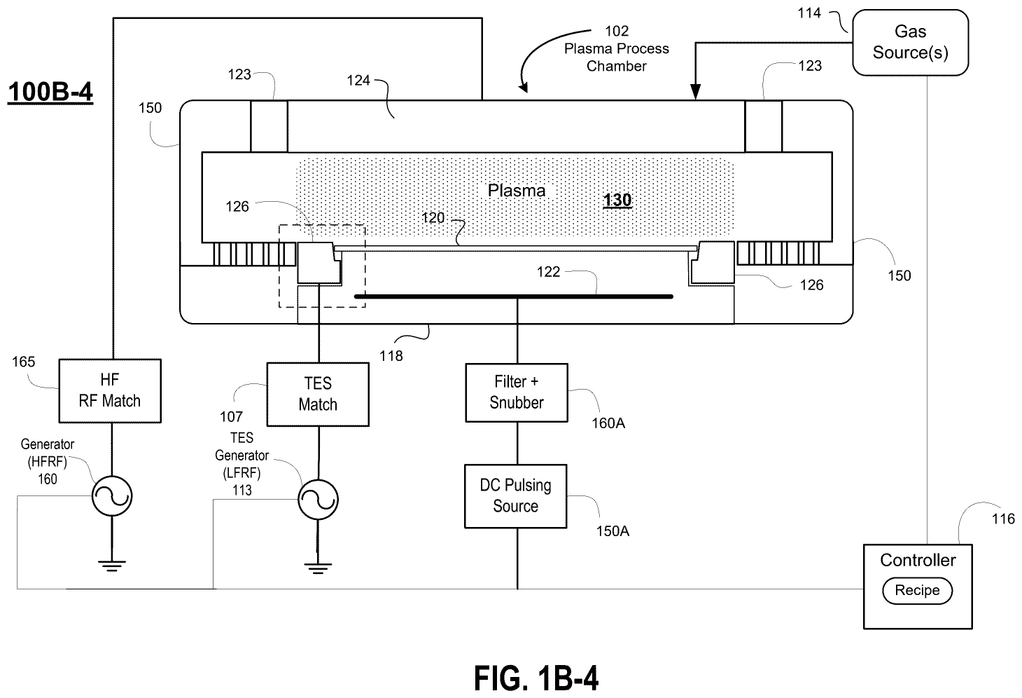

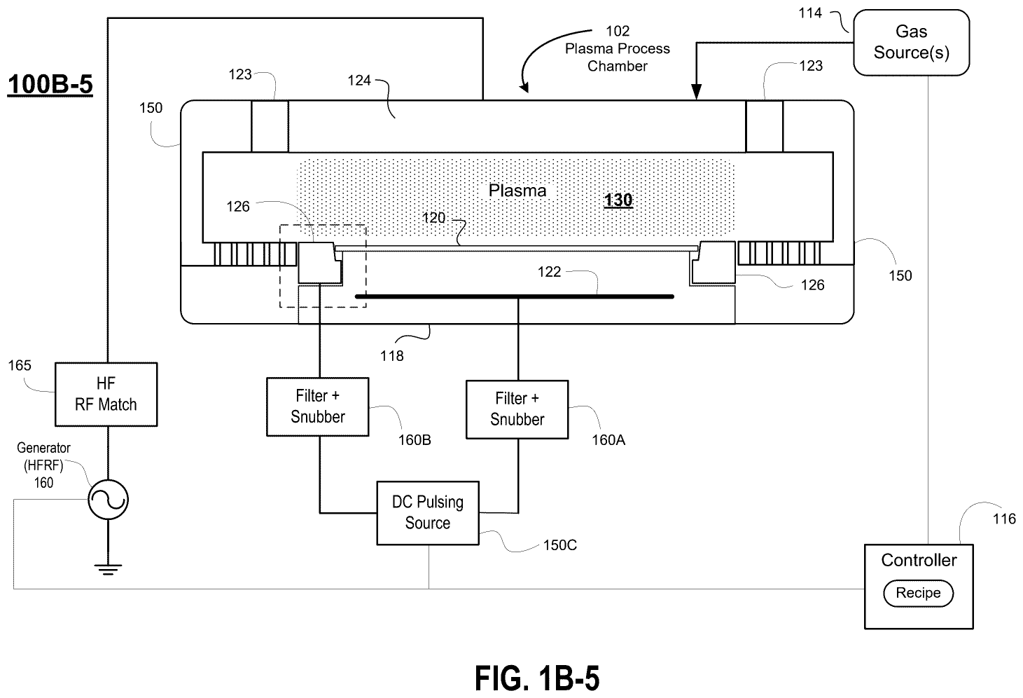

FIGS. 1A and 1B-1 through 1B-5 illustrate exemplary embodiments of plasma processing systems utilized for operations including etching and/or depositing films, in accordance with embodiments of the disclosure. The plasma processing systems are used to process a wafer 120, such as by performing plasma processing of the wafer 120. In particular, FIG. 1A shows a plasma processing system including radio frequency (RF) power sources. The plasma processing systems of FIGS. 1B-1 through 1B-5 show plasma processing systems including at least one pulsed direct current (DC) power source that may or may not be combined with a RF power source. In embodiments, the plasma processing systems are capacitive coupled plasma (CCP) processing systems. In the plasma processing systems of FIGS. 1A and 1B-1 through 1B-5, like components are represented by like reference numerals. The plasma processing systems may be modified depending on design to generate plasma through various methods, inductively coupled plasmas (ICPs), etc. With the various configurations of plasma processing systems, embodiments of the present disclosure implemented to achieve a desired ion tilt at an edge of a wafer based in part on measuring RF current may be implemented on various plasma processing systems (e.g., CCPs, ICPs, etc.) and each of their configuration variations.

In general, the RF power sources in FIGS. 1A and 1B-1 through 1B-5 provide power via sinusoidal or alternating current (AC) signals (i.e., varying voltage signals in sinusoidal form), which may be pulsed or non-pulsed. In addition, the DC power sources in FIGS. 1B-1 through 1B-5 generally provide power via a pulsed DC signal. For purposes of brevity and clarity, the plasma processing systems of FIGS. 1A and 1B-1 through 1B-5 will be described with RF pulsed generators and DC pulsed generators.

In particular, FIG. 1A illustrates an exemplary embodiment of the plasma processing system 100A utilized for etching operations that is configured as a CCP processing system, and includes a CCP plasma process chamber 102. Except for the configurations of power supplies, the description of the plasma processing system of FIG. 1A is generally applicable to the plasma processing systems of FIGS. 1B-1 through 1B-5, wherein like components are represented by like reference numerals. The plasma process chamber 102 includes a substrate support or pedestal, such as an electrostatic chuck (ESC) 118, or magnetic chuck. In embodiments, the ESC may have several circular rings with different material types to achieve a certain capacitive coupling between the ESC and a powered edge ring. A lower electrode 122 may be embedded within the ESC 118. A substrate 120 may be placed on the pedestal for processing, wherein the substrate 120 is processed to make one or more semiconductor chips. Facing the pedestal is an upper electrode 124. As shown, the upper electrode may be coupled to ground. In other embodiments, the upper electrode 124 may be coupled to an RF power supply (e.g., supplying high frequency power, etc.), as will be further described below in relation to FIGS. 1B-2 through 1B-5. The upper electrode 124 may be configured with an extension 123 that may be shaped as a ring. Between the upper electrode 124 and the lower electrode 122 is a gap forming a processing volume within which a plasma 130 may be formed.

The plasma process chamber 102 also includes the edge ring 126, such as a tunable edge sheath (TES) ring, which surrounds the ESC 118. As an example, the edge ring 126 is fabricated from a conductive material, such as silicon, boron doped single crystalline silicon, silicon carbide, an alloy of silicon, or a combination thereof. It should be noted that the edge ring 126 has an annular body, such as a circular body, or ring-shaped body, or dish-shaped body. As an illustration, the edge ring 126 has an inner radius and an outer radius, and the inner radius is greater than a radius of the ESC 118. The edge ring 126 performs many functions including positioning the substrate 120 on the ESC 118, confining plasma to an area above the substrate 120, protecting the ESC 118 from erosion by ions of the plasma, and shielding underlying components of the plasma chamber 102 from being damaged by ions of the plasma. Further, the edge ring is configured to improve performance at the edge of the wafer. For example, by varying an amount of the power coupled to the edge ring, plasma density of the plasma at the edge region, sheath uniformity of the plasma at the edge region; etch rate uniformity of the plasma at the edge region, and ion tilt at which the wafer is etched in the edge region may be controlled.

As shown, plasma processing chamber 102 of FIG. 1A may include a C-shroud 150 that extends from the upper electrode 124 to the ESC 118 including the bottom electrode to provide additional plasma containment. The C-shroud may have a plurality of apertures to allow gas and byproducts to flow out of the C-shroud. The C-shroud may be grounded. In other embodiments, the plasma processing chamber may be configured differently to include confinement rings (not shown) for confining plasma 130 during etching operations.

In another embodiment, the gas source(s) 114 are connected to the plasma process chamber 102 and are configured to inject the desired process gas(es) into the plasma process chamber 102. As an example of plasma formation, after providing one or more RF signals to the ESC 118 and injecting process gas(es) into the plasma process chamber 102, plasma 130 is then formed between the upper electrode 124 and the ESC 118. The plasma 130 can be used to etch the surface of the wafer 120.

The plasma processing system 100A includes multiple power sources including a main generator 110, main generator 112, and TES generator 113. For example, main generator 110 and/or main generator 112 supply a modified signal (supply power) to the lower electrode 122 of ESC 118 via a main impedance match network 106. The match network enables dynamic tuning of power provided to the lower electrode 122 by matching impedance between the load (e.g., plasma chamber and any connecting cabling) and a source (e.g., main HFRF generator 110 and main generator 112 and any connecting cabling). For example, the main generator 110 may be a high frequency (HF) RF generator (HFRF) (hereinafter referred to as main HFRF generator 110), which may be configured to produce high frequencies ranging from and including 13 MegaHertz (MHz) to 120 MHz. For example, the high frequency is a baseline frequency of 13.56 MHz or 27 MHz or 40 MHz or 60 MHz or 100 MHz. Further, the main generator 112 may be a low frequency (LF) RF generator (LFRF) (hereinafter referred to as main LFRF generator 112), which may be configured to produce frequencies ranging from and including 10 kilohertz (kHz) to 800 kHz. For example, the frequency of operation of the main LFRF generator 112 is 400 kHz. Further, the main HFRF generator 110 and/or the main LFRF generator 112 may provide a pulsed or non-pulsed signal. In one embodiment, the power signals are synchronized in a pulsing system, such that within one pulse all three power signals (e.g., from main HFRF generator 110, main LFRF generator 112, and TES generator 113) are on with different levels and states.

In addition, TES generator 113 supplies a power signal to the edge ring 126 via a TES impedance match network 107. The TES power signal may be delivered to an electrode 231 embedded within the edge ring 126 via a power pin 230 that is coupled to the TES impedance match network 107. The TES match network enables dynamic tuning of power provided to the edge ring 126 by matching impedance between the load (e.g., the plasma chamber 102 and any connecting cabling) and a source (e.g., TES generator 113 and any connecting cabling). For example, the TES generator 113 may be a low frequency RF generator (hereinafter referred to as TES LFRF generator 113), which for example may have a frequency of operation of 10 kHz to 800 kHz, etc. For example, the frequency of operation of the TES LFRF generator 113 is 400 kHz. In other embodiments, the TES LFRF generator 113 provides a low frequency signal via a corresponding match network. Further, the TES LFRF generator 113 may provide a pulsed or non-pulsed signal. Control of the power delivered to the edge ring provides for control of ion tilt at the edge of the wafer (e.g., an angle substantially normal to the wafer or perpendicular to the wafer, or at other angles to the wafer), and correspondingly control of the plasma sheath at the edge of the wafer.

In some embodiments, the system may include a controller 116 that is used for controlling various components of the plasma processing system 100A. In one example, the controller 116 can be connected to the plasma generators (e.g., main HFRF generator 110, main LFRF generator 112, and TES LFRF generator 113), to the gas source(s) 114 that are coupled to the plasma process chamber 102, and to other components. The controller 116 includes a processor, memory, software logic, hardware logic and input and output subsystems from communicating with, monitoring and controlling the plasma processing system 100A. In some embodiments, the controller 116 includes one or more recipes including multiple set points and various operating parameters (e.g., voltage, current, frequency, pressure, flow rate, power levels, temperature, timing parameters, process gases, mechanical movement of the substrate 120, etc.) for operating the plasma processing system 100A. For example, depending on the processing being performed, the controller 116 controls the delivery of process gases delivered from the gas source(s) 114 to achieve a designed processing condition, such as to etch features and/or deposit or form films over the substrate 120. The chosen gases are then distributed in a space volume defined between the upper electrode 124 and the substrate 120 resting over the ESC 118.

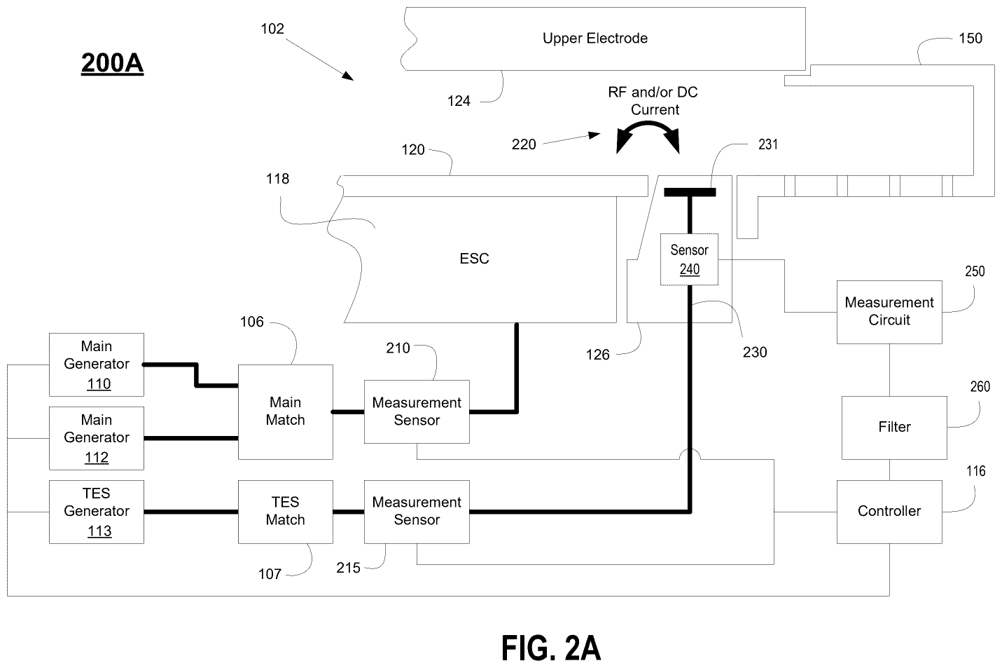

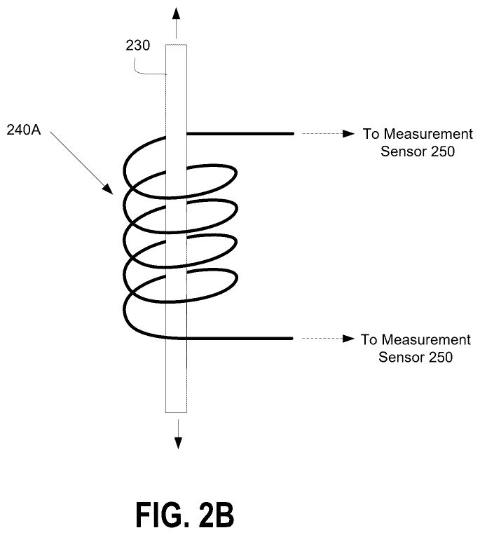

FIGS. 1B-1 through 1B-5 illustrate plasma processing systems including at least one DC power source providing pulsed DC signals, as will be further described below, in accordance with embodiments of the present disclosure. In general, a constant voltage DC signal may be pulsed to provide the pulsed DC signal. Pulsed DC power may provide certain advantages over RF power, such as using less power and not requiring an impedance match network (i.e., as implemented through high voltage cabling and/or snubber circuits, etc.) Further, the plasma processing systems of FIG. 1B-1 and 1B-2 generates plasma through a main HFRF generator 110 that is coupled to the lower electrode 122 of the ESC, wherein the upper electrode 124 is coupled to ground. On the other hand, the plasma processing systems of FIGS. 1B-3 to 1B-5 generate plasma through an HFRF generator 160 via a corresponding HF RF match network 165 that is coupled to the upper electrode 124.

For example, the plasma processing system 100B-1 of FIG. 1B-1 includes a main HFRF generator 110 that provides a pulsed RF signal via the main impedance match network 106 to provide power to the lower electrode 122, in accordance with one embodiment of the present disclosure. In addition, DC pulsing source 150A provides a pulsed DC signal to the lower electrode 122 via a filter and snubber circuit 160A, configured to reduce and/or remove any high frequency harmonics (e.g., through attenuation) and control any oscillation of the signal all of which are caused by the pulsing. In one embodiment, the filter and snubber circuit 160A is located within the main impedance match network 106, and another embodiment, the filter and snubber circuit 160A bypasses the main impedance match network 106. In either case, the main HF RF signal is combined with the DC pulsed signal to drive the lower electrode 122 in order to generate plasma, wherein the upper electrode 124 is coupled to ground. Further, the TES LFRF generator 113 supplies a pulsed RF signal via the TES impedance match network 107 to the edge ring 126.

Also, the plasma processing system 100B-2 of FIG. 1B-2 includes a main HFRF generator 110 that provides a pulsed RF signal via the main impedance match network 106 to provide power to the lower electrode 122, in accordance with one embodiment of the present disclosure. In addition, DC pulsing source 150A provides a pulsed DC signal to the lower electrode 122 via a filter and snubber circuit 160A, configured to reduce and/or remove any high frequency harmonics (e.g., through attenuation) and control any oscillation of the signal all of which are caused by the pulsing. In one embodiment, the filter and snubber circuit 160A is located within the main impedance match network 106, and another embodiment, the filter and snubber circuit 160A bypasses the main impedance match network 106. In either case, the main HF RF signal is combined with the DC pulsed signal to drive the lower electrode 122 in order to generate plasma, wherein the upper electrode 124 is coupled to ground. Further, DC pulsing source 150B provides pulsed DC signals to the TES edge ring 126 via the filter and snubber circuit 160B, which is similarly configured as filter and snubber circuit 160A to reduce and/or remove any high frequency harmonics and control oscillation of the pulsed DC signal.

In addition, the plasma processing system 100B-3 of FIG. 1B-3 includes an HFRF generator 160 that provides a pulsed RF signal via the an HFRF impedance match network 165 to provide power to the upper electrode 124 in order to generate plasma. For example, the HFRF generator 160 may be configured to produce high frequencies ranging from and including 13 MegaHertz (MHz) to 120 MHz, including operating at baseline frequencies of 13.56 MHz or 27 MHz or 40 MHz or 60 MHz or 100 MHz. The match network 165 enables dynamic tuning of power provided to the upper electrode 124 by matching impedance between the load (e.g., plasma chamber and any connecting cabling) and a source (e.g., HFRF generator 160 and any connecting cabling). Also, DC pulsing source 150A provides a pulsed DC signal to the lower electrode 122 via the filter and snubber circuit 160A. In addition, DC pulsing source 150B provides a pulsed DC signal to the TES edge ring 126 via the filter and snubber circuit 160B.

The plasma processing system 100B-4 of FIG. 1B-4 includes an HFRF generator 160 that provides a pulsed RF signal via the an HFRF impedance match network 165 to provide power to the upper electrode 124 in order to generate plasma. Also, DC pulsing source 150A provides a pulsed DC signal to the lower electrode 122 via the filter and snubber circuit 160A. Further, the TES LFRF generator 113 supplies a pulsed RF signal via the TES impedance match network 107 to the edge ring 126.

In other embodiments, for plasma processing systems having pulsed DC signals driving the ESC and TES edge ring, the pulsed DC signals can be generated from a single DC pulsing source. In that manner, there is no time delay between the pulsed DC signals driving the ESC and the TES edge ring. For example, the plasma processing systems of FIGS. 1B-2 and 1B-3 may be configured to include a shared DC pulsing source. For purposes of illustration only, FIG. 1B-5 is shown with modifications to the plasma processing system of FIG. 1B-3. In particular, the plasma processing system 100B-5 includes an HFRF generator 160 that provides a pulsed RF signal via the an HFRF impedance match network 165 to provide power to the upper electrode 124 in order to generate plasma. Also, a shared DC pulsing source 150C provides multiple pulsed DC signals. For example, shared DC pulsing source 150C provides a pulsed DC signal to drive the lower electrode 122 in the ESC 118 via the filter and snubber circuit 160A. Also, the shared DC pulsing source 150C provides another pulsed DC signal to the TES edge ring 126 via the filter and snubber circuit 160B. That is, the shared DC pulsing source 150C provides separate pulsed DC signals to drive the edge ring 126 and the ESC 118 through separate filter and snubber circuits. In another implementation, the shared DC pulsing source can be implemented in the plasma processing system of FIG. 1B-2, such that modifications to the plasma processing system includes a shared DC pulsing source to provide separate pulsed DC signals to drive the edge ring and ESC. In that case, the ESC is driven by both a high frequency pulsed RF signal via a corresponding main impedance match network and a pulsed DC signal to provide power to a lower electrode in the ESC.

In other embodiments, other configurations of HFRF power, LFRF power, and DC power, wherein each power source may be pulsed or non-pulsed, may be utilized for providing power to a corresponding plasma processing system. For example, some implementations may include a LFRF generator coupled via a corresponding LFRF impedance match network to provide a pulsed LFRF signal to the lower electrode, instead of providing a pulsed DC signal.

FIG. 2A illustrates a control system 200A is utilized for achieving a desired ion tilt at the edge of a wafer by measuring RF current at the interface between an ESC and an edge ring, in accordance with one embodiment of the disclosure. For purposes of illustration, control system 200 may be adapted for implementation within the exemplary plasma processing systems of FIGS. 1A and 1B-1 through 1B-5. For example, for purposes of brevity and clarity the control system 200A includes a plasma processing system that is described in FIG. 1A (i.e., CCP plasma processing system 100A including RF power sources coupled to the TES edge ring and the ESC. However, the control system shown in FIG. 2A could be implemented in any of the power configurations of plasma processing systems described, in part, by FIGS. 1A and 1B-1 through 1B-5 (i.e., implementing various configurations of RF power and DC power sources that can be pulsed or non-pulsed).

It is difficult to meet process specifications at the edge of a substrate 120 due to a tradeoff between a profile angle or ion tilt at which the substrate is etched and an etch rate. Ion tilt and/or etch rate may be influenced by the interaction between the wafer plasma sheath (i.e., plasma over the ESC 118 and substrate 120) and the edge ring plasma sheath (plasma beyond the edge of the substrate 120 and over the edge ring 126). For example, it may be beneficial to control the thicknesses of or control the plasma density between the wafer plasma sheath and the edge ring plasma sheath, especially at the interface between the ESC 118 and the edge ring 126. In embodiments of the present disclosure, control may be achieved in part by generating a desired ion tilt from contributions of the wafer plasma sheath and the edge ring plasma sheath at the interface, wherein the desired ion tilt is achieved in part through measurement of the RF and/or pulsed DC current at the interface.

The control system 200A implements a control scheme for controlling the tunable edge ring plasma sheath or TES plasma sheath. As shown, RF power is independently applied to the substrate 120 (e.g., via ESC 118) and the capacitively coupled edge ring 126 by multiple generators. In particular, the plasma sheaths above the wafer and the edge of the substrate are driven by separate RF generators, but can be configured to provide any type of power (e.g., RF, DC, AC, pulsed, non-pulsed, etc.). For example, main HFRF generator 110 and main LFRF generator 112 may be configured as master RF generators with the TES generator 113 configured as a slave RF generator. As previously described, in other configurations the generators may be configured as DC pulsed generators providing a pulsed DC signal. In general, magnitudes of plasma sheath voltages and phase angles between the wafer plasma sheath and edge ring plasma sheath can be monitored by voltage pickups (e.g., voltage sensors, etc.). The magnitude of each plasma sheath can be adjusted to achieve process results (e.g., one or more factors, etc.) at the wafer edge, as will be described below.

The master and slave generators are operating at the same RF frequency, in one embodiment. For example, RF voltages and phases of the RF power signals are measured at outputs of the main impedance match network 106 and the TES impedance match network 107 by the measurement sensors and/or circuits 210 and 215. In some embodiments, the measurement sensors and/or circuits are incorporated into the match networks, such that measurement sensor and/or circuit 210 is included within impedance match network 106 and measurement sensor and/or circuit 215 is included within impedance match network 107. In configurations where the plasma processing systems include DC pulsed signals delivering power to the TES 126 and/or the ESC 118, the corresponding measurement sensor and/or circuit may be included within the power source (e.g., voltage sensor located within a DC pulsing source) for regulating the same power source, for example. The measurements may be delivered to controller 116, or a power generator configured as a controller (e.g., slave TES generator 113). After measurements, frequency of the LFRF generators may be adjusted to operate at the same value and locked. For example, TES LFRF and/or main LFRF power generators (e.g., providing RF power to the ESC) may be locked, LFRF TES power generator and main DC pulsing source (e.g., providing DC power to the ESC) may be locked, etc.). In particular, measurement sensor 210 is coupled to the main impedance match network 106, and is configured to measure the modified RF signal provided by main LFRF generator 112. For example, measurement sensor 210 may be configured to measure the voltage and/or phase of contributions of the main LFRF generator 112 from the modified RF signal (combined power from the main LFRF generator 112 and the main HFRF generator 110), provided to the ESC 118, at the output of the main impedance match network 106. In other power configurations of corresponding plasma processing systems, the measurement sensor is configured to measure voltage and/or phase of the DC pulsed power sources. In addition, measurement sensor 215 is coupled to the TES impedance match network 107, and is configured to measure the TES signal provided by the TES generator 113. For example, measurement sensor 215 may be configured to measure the voltage and/or phase of the TES signal, provided to the edge ring 126) at the output of the TES impedance match network 107, wherein the TES signal may be an RF signal (pulsed or non-pulsed sinusoidal signal) or a pulsed DC signal.

In particular, the control scheme of control system 200A controls parameters of the edge ring plasma sheath by controlling and/or achieving a desired ion tilt at an edge of a wafer through a measurement of the RF and/or pulsed DC current 220 passing across, by, and/or through the interface of the ESC and edge ring and adjusting power or phase relationships between the RF generators (e.g., various configurations of main HFRF generator 110, main LFRF generator 112, TES LFRF generator 113, and DC pulsed generators). As shown, sensor 240 is placed at a suitable location for measuring the current 220 (e.g., RF and/or pulsed DC current) across the interface between the ESC 118 and the edge ring 126, such as within the edge ring 126 and adjacent to or surrounding the power pin 230. Readings from sensor 240 are delivered to the measurement circuit 250 which outputs one or more measurements of the RF and/or pulsed DC current 220, such as a magnitude and/or phase of the current signal 220. One or more measurements of the current signal 220 are delivered to the controller 116.

In one embodiment, one or more measurements of the current signal 220 are filtered by the filter 260. For example, filter 260 may be configured to remove components of the current signals and/or measurements contributed by the main HFRF generator 110, such that measurements of the current signal 220 include only the low frequency components of the current signal and/or measurements contributed by the main LFRF generator 112, the TES LFRF generator 113 and/or any DC pulsing sources. For purposes of illustration, filter 260 may be configured as a band-pass filter that removes contributions from high frequency power sources.

Based on the measurements of the current signal 220 (e.g., phase and/or amplitude of the RF and/or pulsed DC current), the slave output value is set to a specific value that corresponds to desired process results at the wafer edge. That is, the voltage and/or phase (e.g., phase launch point) of the TES signal from the TES LFRF generator 113 (or a corresponding DC pulsing source) is adjusted to achieve the desired results. As such, deliberate adjustment and/or control of the TES signal adjusts the edge plasma sheath at the wafer edge to achieve a pre-determined performance at the wafer edge, for example, a normal (i.e., 0 degree tilt that is perpendicular to the wafer) edge or ion tilt at the wafer edge, a predetermined edge or ion tilt at the wafer edge, etc.

FIG. 2B illustrates an exemplary sensor 240A configured to measure the current (e.g., RF and/or pulsed DC current) at the interface between an ESC and an edge ring, in accordance with one embodiment of the present disclosure. In particular, sensor 240A is one of the embodiments of sensor 240 of FIG. 2A that are configured for measuring the current across the interface between the ESC 118 and the edge ring 126 of a plasma processing system, and is shown for purposes of illustration only. That is, other sensors are well suited for measuring the current across the interface (i.e., Rogowski coil, Hall effect sensors, etc.)

As shown and for purposes of illustration only, sensor 240A is configured as a transformer. Sensor 240A is designed to produce a current signal that is reflective of the current 220 across the interface between the ESC 118 and the edge ring 126. In particular, the current 220 generated across the interface will also flow through the power pin 230. Sensor 240A configured as a transformer is configured to measure the current flowing through the power pin 230. For example, the transformer will generate a current that is reflective of the current flowing through the power pin 230 and correspondingly reflective of the current 220. For purposes of illustration only, a current generated by the transformer is proportional to the current flowing through the power pin, which corresponds to the current 220 flowing across the interface. The proportion of the current generated by the transformer can be selected by design (e.g., proportion may be based in part on the number of coils in the transformer). In that manner, the current 220 flowing across the interface can be determined based on the current generated by the transformer.

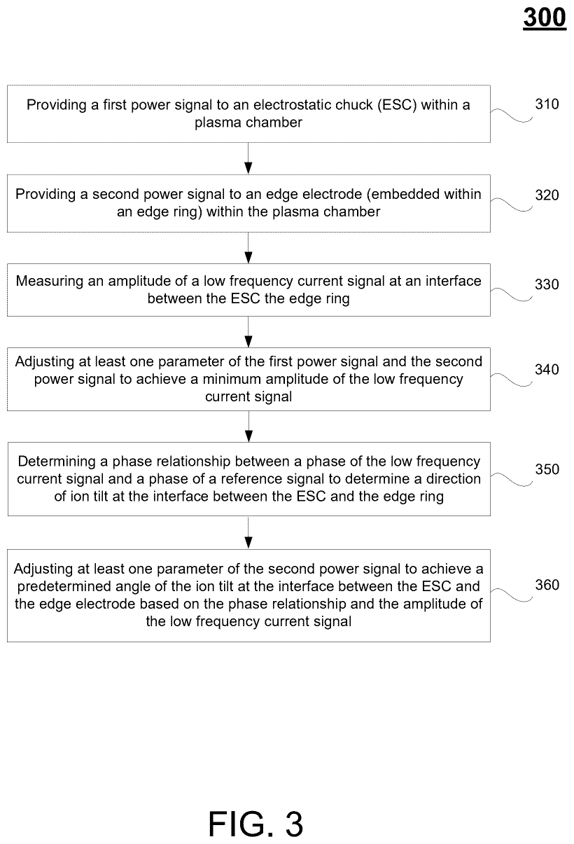

FIG. 3 is a flow diagram 300 illustrating a method for achieving a desired ion tilt at the edge of a wafer by measuring a low frequency current (e.g., RF and/or pulsed DC current) at the interface between an ESC and an edge ring, in accordance with one embodiment of the disclosure. The method of flow diagram 300 may be implemented to control processes in the plasma processing systems of FIGS. 1A and 1B-1 through 1B-5, as well as for other plasma processing systems. For example, the method of flow diagram 300 may be stored in computer-readable form in memory accessible by control module 116 of FIGS. 1A and 1B-1 through 1B-5 in order to perform the operations of flow diagram 300. Though flow diagram may be generally applied to various configurations of plasma processing systems, for purposes of illustration certain operations may be described with reference to a plasma processing system including pulsed RF generators, such as those in FIG. 1A.

At 310, the method includes providing a first power signal to an ESC within a plasma chamber. In general, the first power signal provides at least a low frequency power signal to the ESC. Depending on the configuration of a corresponding plasma processing system, the first power signal may be an RF signal that is pulsed or non-pulsed or a pulsed DC signal. When the first power signal is generating plasma, there may be a high frequency and a low frequency component to the first power signal. For example, in a plasma processing system including pulsed RF power generators, the first power signal is provided via a first impedance matching circuit to an electrostatic chuck (ESC). In particular, the first power signal is an RF signal generated from a first RF signal and a second RF signal. The first RF signal is provided from a first high frequency RF generator, which is provided to the impedance matching circuit. The second RF signal is provided from a low frequency RF generator and provided to the impedance matching circuit. The first RF signal and the second RF signal are combined such that the first impedance matching circuit outputs the first power signal that is delivered to the ESC.

At 320, the method includes providing a second power signal to an edge ring within the plasma chamber. In general, the second power signal provides a low frequency power signal to the edge ring. Depending on the configuration of the corresponding plasma processing system, the second power signal may be an RF signal that is pulsed or non-pulsed or a pulsed DC signal. For example, in a plasma processing system including pulsed RF power generators, the second power signal is provided via a second impedance matching circuit to an edge ring within the plasma chamber. In one embodiment, the second power signal is a third RF signal that is generated from the first low frequency RF generator which is provided to the second impedance matching circuit which outputs the second power signal delivered to the edge ring. In one embodiment, the first power signal and the second power signal are locked in frequency. For example, in a plasma processing system including pulsed RF power generators, all the power signals from the various RF power generators are locked to a frequency. In one particular embodiment, in the plasma processing system including pulsed RF power generators, at least the low frequency power generators are locked to a frequency. That is, at least the low frequency components of the first power signal and the second power signal are locked to a frequency, such as the second RF signal (e.g., low frequency RF to the ESC) and the third RF signal (low frequency RF to the edge ring) are locked to a frequency.

In other embodiments, a pulsed DC signal is delivered to at least one of the ESC and the edge ring, as previously described. For example, in one configuration of a plasma processing system, power delivery to the electrode in the ESC is a pulsed DC signal at a high voltage optionally combined with a high frequency RF signal and the power signal to the edge ring is low frequency pulsed RF signal. In another configuration, the power delivery to the electrode in the ESC is a pulsed DC signal at a high voltage optionally combined with a high frequency pulsed RF signal and the power signal to the edge ring is a pulsed DC signal. In another configuration, the power delivery to the electrode in the ESC is pulsed DC at a high voltage and the power signal to the edge ring is also a pulsed DC signal, both pulsed at the same frequency. In still another configuration, the power delivery to the electrode in the ESC is a pulsed DC signal at a high voltage and the power signal to the edge ring is a pulsed RF signal. The pulsing high voltage DC source (e.g., component of the main power) produces sufficient voltage at the ESC to drive positive ions to the substrate due to a negative self-bias action of the substrate. In still other embodiments, the main power delivery and the power signal to the edge ring are RF power signals, which can be pulsed or non-pulsed. In still other embodiments, the main power delivery and the power signal to the edge ring and the power signal to the edge ring are a combination of RF and DC power signals, pulsed and non-pulsed.

At 330, the method includes measuring an amplitude of a low frequency current signal occurring at an interface between the ESC and the edge ring. In one embodiment, the current signal is an RF current signal across the interface, such as when power delivery systems to the main electrode of the ESC and the electrode in the edge ring are RF signals operating at the same frequency. In other embodiments, the current signal is an RF and/or pulsed DC current signal across the interface. Measurement of the low frequency current in the present embodiments gives a more direct measurement of the current occurring at the interface, and is independent of the drive impedances of the power sources supplying power to the ESC and the edge ring. This provides an advantage over previous systems that relied on voltage sensors remote (i.e., downstream) from the interface between the ESC and edge ring to set a predetermined phase relationship between power signals delivered by separate generators operating at the same frequency, wherein the predetermined phase relationship gives a desired result (e.g., desired ion tilt). In the previous systems, the voltage measurements had inaccuracies that give different phase information based on the source impedances of the match network, the length of the RF cable feeding the edge rings, the filter at the end of the RF cable.

In one embodiment, the low frequency current signal that is measured is filtered to remove contributions of high frequency components generated by the first RF signal (e.g., generated by the HFRF generator) from the RF current signal. This is to focus on the contributions of the second low frequency RF signal (e.g., low frequency RF signal from the low frequency RF generator). For example, when the second RF signal is at 400 kHz, the current signal that is measured is filtered to obtain the amount of 400 kHz current at the interface.

At 340, the method includes adjusting one or more parameters of the first power signal and the second RF signal to achieve a minimum amplitude of the low frequency current signal that is measured. In particular, without wishing to be bound by theory or mechanism of action, it is believed that the amount of the current signal passing through the interface has a correlation to ion tilt control. As such, the current (e.g., RF and/or pulsed DC currents) at the interface between the ESC and edge ring is measured for purposes of balancing the power and/or voltages at the interface. More specifically, when the phase between voltage signals provided by the first power signal or main power signal delivered to the ESC and the second power signal delivered to the edge ring are at a nominal value (e.g., at the same phase) for a given edge ring voltage setpoint, the RF current between the ESC and the edge ring is at a minimum value, such that the power and/or voltages provided by the power supplies are balanced at the interface. For purposes of illustration when the power and/or the voltages are balanced at the interface, the plasma sheath along the edge ring 126 becomes coplanar with the plasma sheath along the wafer sheath during a given pulse which results in the ion incidences being substantially normal to the substrate (i.e., at 0 degrees or perpendicular to the substrate). As a result, ion angular spread (e.g., ion tilt angles) at the extreme edge of a substrate is reduced or eliminated

At 350, the method includes determining a phase relationship between the phase of the low frequency current signal and a reference signal to determine a direction of ion tilt at the interface between the ESC and the edge ring. For example, amplitude and phase of the low frequency current signal at the interface is measured. In addition, a phase of the reference signal may be measured. In one embodiment, the reference signal is the main low frequency RF power signal. In particular, when the phase of the low frequency current signal lags the phase of the reference signal, this may indicate that the direction of the ion tilt at the interface of the ESC and the edge ring is either towards the center of the substrate or away from the center of the substrate. Conversely when the phase of the low frequency current signal leads the phase of the reference signal, this may indicate an opposite effect, such that if the direction of the ion tilt is towards the center of the substrate when the phase of the low frequency current signal lags the phase of the reference signal, then the direction of the ion tilt is opposite or away from the center of the substrate when the phase of the low frequency current signal leads the phase of the reference signal.

At 360, the method includes adjusting at least one parameter of the second power signal (e.g., TES signal) to achieve a predetermined angle of the ion tilt at the interface between the ESC and the edge ring based on the phase relationship and the amplitude of the low frequency current signal. In particular, as previously described the phase relationship may give a direction of the ion tilt based on metrology (i.e., towards the center of the substrate or away from the center of the substrate, and the magnitude of the low frequency current signal may give a magnitude of the direction or an angle from vertical (i.e., 0 degrees). For example, voltage signals at suitable locations can be measured to establish a metrology that determines amplitude, phase relationships, and/or time delays of arriving signals at the ESC and across the interface between the ESC and the powered edge ring that produce desired results (e.g., desired ion tilt angles, etc.). Generally, it is understood that adjusting relative power or voltage, the phase relationship, and/or time delay between the power signals provided to the ESC and the edge ring can be used to control the vector direction of the electric field across the interface between the ESC and the edge ring. The metrology further extends the understanding to include adjusting relative power or voltage, the phase relationship, and/or the time delay between the TES signal and the low frequency current signal measured at the interface to achieve the same control of the vector direction of the electric field across the interface. For example, the power or voltage, the phase relationship, and/or time delay of the power and/or current signals can be adjusted by modifying one or more parameters of the TES signal provided to the edge ring. This adjustment of the power or voltage, phase, and/or time delay relationship of the power and/or low frequency current signals either draws more power from the electrode in the ESC toward the edge of the substrate, or pushes more power at the interface towards the ESC.

In particular, in one embodiment the phase relationship is determined between the low frequency RF signal provided to the ESC and the low frequency RF current signal. This phase relationship may be controlled by adjusting the one or more parameters of the TES signal. In that manner, the phase relationship may be adjusted to ensure that the signals reach the interface with the same amplitude and having no or some degree of phase difference at the interface in order to cancel each other out and generate a minimum low frequency current (e.g., RF current) at the interface. For instance, to generate approximately net zero (0) current at the interface, in some cases the degree of phase difference at the interface may be approximately zero (0) degrees (where the signals arrive at the interface with the same amplitude and generate a network current of zero (0) through the interface), in other cases the degree of phase difference may be approximately +/−180 degrees out of phase, and in other cases, the degree of phase difference may be a value between 0 and +/−180 degrees. In another embodiment, a time delay of the pulsed DC signal to the ESC and/or a time delay of the pulsed DC signal to the TES edge ring are considered. That is, the length of cabling between a corresponding pulsed DC generator and the ESC or the TES edge ring generates a time delay of the corresponding pulsed DC signal. The relationship between the time delays of the pulsed DC signals to the TES edge ring and the ESC is determined and may be adjusted to ensure that the signals reach the interface with the same amplitude but approximately +/−180 degrees out-of-phase in order to cancel each other out and generate a minimum low frequency current (e.g., about 400 KHz) at the interface.

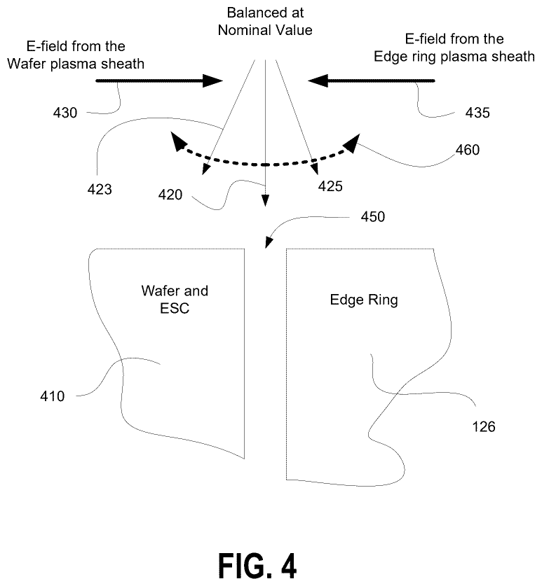

For example, FIG. 4 shows the effective local electric field across the interface 450 is influenced by the electric field 430 of the wafer plasma sheath and the electric field 435 of the edge ring plasma sheath, in accordance with one embodiment of the present disclosure. When the power provided by the power source to the ESC and/or substrate combination 410 is balanced with the TES power source to the edge ring 126, the electric fields are canceled (i.e., effective electric field is zero (0)) which results in an ion tilt 420 of 0 degrees. The ion tilt can be adjusted by adjusting the power or voltage, the phase relationship, and/or the time delay of the power and/or current signals, such as by modifying one or more parameters of the TES signal supplying power to the edge ring. In one embodiment, the launch point of the TES signal is adjusted to achieve the desired result (e.g., desired ion tilt), as established by the metrology. In another embodiment, the voltage of the TES signal is adjusted to achieve the desired result, such as a desired ion tilt that is angled away from 0 degrees (e.g., as shown by various angles on dotted line 460), as established by the metrology. Purely for example, the voltage of the TES signal may be increased to push more power from the edge ring to the ESC (e.g., from the electric field of the edge ring plasma sheath), thereby achieving an ion tilt (e.g., tilt 423) that is directed to the center of the substate. Correspondingly, the voltage of the TES signal may be decreased to pull power towards the edge ring, thereby achieving an ion tilt (e.g., tilt 425) that is directed away from the center of the substrate.

In one embodiment, when applying a pulsing high voltage DC source supplying power to the ESC, there may be need for some precautions. For example, DC pulsing provides a high inrush current that drives the total capacitance that hardware of the process chamber presents to the power source. In one case, DC pulsing will generate ringing at the output of the power source that is determined by natural resonances of the chamber hardware and lower electrode feed system acting like a transmission line with a certain characteristic impedance. A suitable snubber network can be used to reduce the ringing effect and provide a smoother but still fast rise and fall time. For example, the snubber network may limit voltage transience (e.g., spikes in voltage). The snubber and/or pulse shaping network may consist of one or more of resistors, inductors, capacitors, a clamping or crowbar diode, and other circuit elements.

In embodiments, a substrate positioning program may include program code for controlling chamber components that are used to load the substrate onto a pedestal or chuck and to control the spacing between the substrate and other parts of the chamber such as a gas inlet and/or target, which may be implemented by control system 116 or controller of FIGS. 1A and 1B-1 through 1B-5. In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor wafer or substrate. The controller, depending on the processing requirements and/or the type of system, may be programmed to control any of the processes disclosed herein, and process implemented for operating a plasma chamber. Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” of all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, a plasma enhanced chemical vapor deposition (PECVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A method, comprising:
providing a first power signal to an electrostatic chuck (ESC) within a plasma chamber;
providing a second power signal to an edge ring within the plasma chamber;
measuring an amplitude of a low frequency current signal occurring at an interface between the ESC and the edge ring;
adjusting one or more parameters of the first power signal and the second power signal to achieve a minimum amplitude of the low frequency current signal;
determining a phase relationship between a phase of the low frequency current signal and a phase of a reference signal to determine a direction of ion tilt at the interface between the ESC and the edge ring; and
adjusting at least one parameter of the second power signal to achieve a predetermined angle of the ion tilt at the interface between the ESC and the edge ring based on the phase relationship and the amplitude of the low frequency current signal.

2. The method of claim 1, further comprising:
providing a first RF signal from a first high frequency RF generator via a first impedance matching circuit; and
providing a second RF signal from a low frequency RF generator via the first impedance matching circuit; and
combining the first RF signal and the second RF signal in the first impedance matching circuit to generate the first power signal,
wherein the low frequency current signal is an RF current signal.

3. The method of claim 2, further comprising:
providing a third RF signal from the low frequency RF generator to a second impedance matching circuit to generate the second power signal.

4. The method of claim 3, further comprising:
locking the second RF signal from the low frequency RF generator and the third RF signal from the low frequency RF generator to a frequency.

5. The method of claim 2, further comprising:
filtering out contributions of the first RF signal provided by the first high frequency RF generator from the low frequency current signal.

6. The method of claim 2,
wherein the reference signal is the second RF signal from the low frequency RF generator as a component of the first power signal.

7. The method of claim 1, further comprising:
adjusting at least one of a launch point and voltage and time delay of the second power signal to achieve the predetermined angle of the ion tilt.

8. The method of claim 1, further comprising:
pulsing in synchronization the first power signal and the second power signal.

9. The method of claim 1, wherein the first power signal and the second power signal include:
a pulsed RF signal; or
a continuous RF signal; or
a pulsed DC signal.

10. A non-transitory computer-readable medium storing a computer program for performing a method, the computer-readable medium comprising:
program instructions for providing a first power signal to an electrostatic chuck (ESC) within a plasma chamber;
program instructions for providing a second power signal to an edge ring within the plasma chamber;
program instructions for measuring an amplitude of a low frequency current signal occurring at an interface between the ESC and the edge ring;
program instructions for adjusting one or more parameters of the first power signal and the second power signal to achieve a minimum amplitude of the low frequency current signal;
program instructions for determining a phase relationship between a phase of the low frequency current signal and a phase of a reference signal to determine a direction of ion tilt at the interface between the ESC and the edge ring; and
program instructions for adjusting at least one parameter of the second power signal to achieve a predetermined angle of the ion tilt at the interface between the ESC and the edge ring based on the phase relationship and the amplitude of the low frequency current signal.

11. The non-transitory computer-readable medium of claim 10, further comprising:
program instructions for providing a first RF signal from a first high frequency RF generator via a first impedance matching circuit; and
program instructions for providing a second RF signal from a low frequency RF generator via the first impedance matching circuit;
program instructions for combining the first RF signal and the second RF signal in the first impedance matching circuit to generate the first power signal,
program instructions for providing a third RF signal from the low frequency RF generator to a second impedance matching circuit to generate the second power signal,
wherein the low frequency current signal is an RF current signal.

12. The non-transitory computer-readable medium of claim 11, further comprising:
program instructions for locking the second RF signal from the low frequency RF generator and the third RF signal from the low frequency RF generator to a frequency.

13. The non-transitory computer-readable medium of claim 11, further comprising:
program instructions for filtering out contributions of the first RF signal provided by the first high frequency RF generator from the low frequency current signal.

14. The non-transitory computer-readable medium of claim 11, further comprising:
program instructions for adjusting at least one of a launch point and voltage and time delay of the second power signal to achieve the predetermined angle of the ion tilt.

15. The non-transitory computer-readable medium of claim 11, wherein in the method the first power signal and the second power signal include:
a pulsed RF signal; or
a continuous RF signal; or
a pulsed DC signal.

16. A computer system comprising:
a processor;
memory coupled to the processor and having stored therein instructions that, if executed by the computer system, cause the computer system to execute a method, comprising:
providing a first power signal to an electrostatic chuck (ESC) within a plasma chamber;
providing a second power signal to an edge ring within the plasma chamber;
measuring an amplitude of a low frequency current signal occurring at an interface between the ESC and the edge ring;
adjusting one or more parameters of the first power signal and the second power signal to achieve a minimum amplitude of the low frequency current signal;
determining a phase relationship between a phase of the low frequency current signal and a phase of a reference signal to determine a direction of ion tilt at the interface between the ESC and the edge ring; and
adjusting at least one parameter of the second power signal to achieve a predetermined angle of the ion tilt at the interface between the ESC and the edge ring based on the phase relationship and the amplitude of the low frequency current signal.

17. The computer system of claim 16, the method further comprising:
providing a first RF signal from a first high frequency RF generator via a first impedance matching circuit; and
providing a second RF signal from a low frequency RF generator via the first impedance matching circuit;
combining the first RF signal and the second RF signal in the first impedance matching circuit to generate the first power signal; and
providing a third RF signal from the low frequency RF generator to a second impedance matching circuit to generate the second power signal,
wherein the low frequency current signal is an RF current signal.

18. The computer system of claim 17, the method further comprising:
filtering out contributions of the first RF signal provided by the first high frequency RF generator from the low frequency current signal.

19. The computer system of claim 16, the method further comprising:
adjusting at least one of a launch point and voltage and time delay of the second power signal to achieve the predetermined angle of the ion tilt.

20. The computer system of claim 16, wherein in the method the first power signal and the second power signal include:
a pulsed RF signal; or
a continuous RF signal; or
a pulsed DC signal.
